(19) United States
(12) Patent Application Publication
(10) Pub. No.: US 2019/0062155 A1
(43) Pub. Date: Feb. 28, 2019

(54) MICROSTRUCTURED SURFACE HAVING DISCRETE TOUCH AESTHETICS

(71) Applicants: Hoowaki, LLC, Greenville, SC (US); BvW Holdings AG, Cham (CH)

(72) Inventors: Ralph A. Hulseman, Greenville, SC (US); Cameron McPherson, Easley, SC (US); Nakul Ravikumar, Greenville, SC (US); Lukas Blucher Von Wahlstatt, Eurasburg (DE)

(21) Appl. No.: 16/116,758

(22) Filed: Aug. 29, 2018

Related U.S. Application Data
(60) Provisional application No. 62/551,492, filed on Aug. 29, 2017.

(51) Int. Cl. B81C 1/00

(52) U.S. Cl. CPC B81C 1/00206; B81C 2201/0154; B81B 2203/0376; B81C 1/00031

(57) ABSTRACT

A method for providing a microstructured surface comprising selecting a material having a desired hardness; selecting a microstructure pattern having an arrangement of microfeatures providing a touch aesthetic to be applied to said material, wherein the width and aspect ratio of the microstructures are configured to provide said touch aesthetic for the hardness of the material selected; selecting said microstructure pattern to further include a physical property independent of said touch aesthetic to be applied to said material, wherein at least one of a pitch and spacing of said microfeatures is configures to provide said physical property; determining the dimensions of said microstructure pattern to be applied to the surface of said material to achieve the desired properties; and, applying the microstructure pattern to said material.

### BACKGROUND OF THE INVENTION

### 1) Field of the Invention

This invention is directed to a microstructured surface having an engineered surface exhibiting touch aesthetics as a physical property of the surface.

### 2) Description of the Related Art

Human each day experience a wide variety of touch aesthetics that occur in nature. This may be the skin of an infant, the fur of a pet, the roughness of tree bark, the prickle of a cocklebur or sunflower stalk, or the slick hardness of a polished stone. In contrast manmade surfaces, particularly on molded goods, tend to feel artificial like plastic.

Certain touch sensations can result in a pleasurable effect on humans such as “velvet soft”. Other touch sensations can result in discomfort and even pain such as “prickly”. Product designers have for many decades spent much effort to design molded products that have improved appearance. Techniques like chemical etching, engraving and more recently laser engraving of mold surfaces to make rubber and plastic articles provide a wide range of appearances including leather, tree bark, basket weave, diamond, and a variety of polishes. However, even though the appearance varies widely, the touch aesthetic still feel unpleasant and artificial. Product designers desire to augment visual aesthetics with touch aesthetics so that molded rubber and plastic goods can feel are variety of ways such as skin-like, fur-like, or tree bark-like to better serve a wide range of consumer tastes and needs. To enable the design process for touch aesthetics, new tools are needed.

There is a need for a common written nomenclature describing a range of touch sensations. There is also a need for an algorithm connecting the nomenclature to design parameters for a micro surface. Using the design parameters and knowledge of the desired material, a micro surface can then be designed to deliver a wide range of touch sensations such as found in nature. This ability would offer many advantages over current surface treatments and designs. For example, a customer might desire that their phone case feels like a particular flower petal.

Certain sensations can also provide utility such as haptic feedback as disclosed in United States Patent Application Publication 2013/0207793 which discloses electroactive transducers as well as methods of producing a haptic effect in a user interface device simultaneously with a sound generated by a separately generated audio signal and electroactive polymer transducers for sensory feedback applications in user interface devices as disclosed. Additionally, there has been research suggesting that touch is truly fundamental to human communication, bonding, and health. On the other hand, certain tactile sensations serve as warning and assist to prevent harm to humans, such as the pain felt when we contact sharp objects.

Each of these tactical sensations are designed to improve user experiences with such items as consumer products, tools, apparel and other items that generally have manmade surfaces. For example, the touch pad of a portable computer as shown in U.S. Pat. No. 7,119,291.

With our increased understanding of the effect of touch and tactile feel of surfaces on humans, there is a growing desire to provide proper tactile sensation experiences with consumer products as well as other surfaces in which we frequently interact. For example, U.S. Pat. No. 5,834,668 discloses a keyboard apparatus having keys that are relatively light in weight and low in cost and yet provide a “good key touch feeling”.

Such efforts to provide touch sensations can effect purchasing decisions (including desirability of consumer goods), emotional feeling, and mental attitude, according to one study. In this study, a Johns Hopkins neuroscientist concluded that due to the complex and counterintuitive system of human touch, our scientific understanding of touch, especially how it is processed in the brain, is much more limited when compared to our knowledge of other senses. However, we know that there are two distinct and parallel pathways to the brain for processing touch: a sensory pathway that includes facts about touch such as vibration, pressure, location and fine texture and one for processing social, and emotional information concerning the emotional content of different sensors of the skin (e.g. pleasure and pain centers of the brain).

As more and more synthetic materials comprise our environments, the less opportunities there are for surfaces to include touch sensations directed to our ability to process and be effected be touch. One attempt to provide a synthetic surface that purports to provide an interactive platform for the simulation of auditory and haptic experiences of everyday materials in walking is reported in a recent article. See Yon Visell, et al., An Architectural Platform for Audio-Haptic Simulation in Walking, Proc. Of the 4th Intl. Conf. on Enactive Interfaces (ENACTIVE 2007), Grenoble, France, (2007). However, these methods seek to use technologies for generating virtual experiences of material with the intrinsically tangible, physical, and spatial experience. These attempts to provide touch sensation with manmade materials have not focused on the material surfaces themselves. It would be desirable to have an engineered surface where the touch sensation properties of the surface can be designed and manufactured with a degree of confidence that the touch sensation will be fairly consistent across individuals.

With the exception of crystals, flat smooth surfaces are fairly rare in nature. However, flat or polished surfaces are quite common in manmade articles such as glass, composites, plastics, sanded wood, etc. It would be advantageous to provide a manmade surface that retained the physical properties such as strength, durability and ease of manufacturer while also having improved touch aesthetics provided to the individual. Such applications are wide ranging from tools, sporting equipment, accessories including jewelry, consumer products such as touch screen and computer touch pads, and others. One attempt to provide for improved touch sensation includes United States Patent Application Publication 20080305305 that discloses a skin material having a uniform thickness and improved touch such as moist (supple) feel and smoothness without deterioration in material appearance for automotive interior applications. This material is described as a substrate having a polymeric layer with a first surface adhering to the substrate and a second surface exposed to the outside and formed with a pattern of fine recesses wherein the fine recesses have a depth of 30 to 130 μm and a projected area ratio of 5 to 20% with respect to the total projected area of the second surface of the polymeric layer. However, this reference is very limited to a specific touch aesthetic in a narrow range of surface structure and cannot provide an engineered surface with multiple touch aesthetics.

Further attempts to provide surfaces with specific touch sensations include coatings such as with Teflon, sandpaper, and adhesives, for example, the HTC Hero, released around 2009, is a cell phone with a Teflon coated case. Further, such attempts such as sandpaper do not have reproducible or consistent surface configurations as the deposition of material (sand) on the substrate (paper) is generally in a random pattern. Further, coating and adhesives cannot be applied to a wide range of materials such as rubber, plastic, polymers, or metals. Use of coatings and other additives have their disadvantages and it would be advantageous to have an engineered surface that provides predictable and reproducible touch aesthetic without relying on coatings.

An object of the present invention is to provide a touch map so that a consumer product such as a phone case can be designed by locating the touch sensation of a desired object (e.g. flower petal) and designing the product with this characteristic.

It is another object to provide for a system or method that allows a designer to use the touch map to find the micro surface design parameters required to create a man-made surface that feels like the desired surface.

It is an object to provide a system or method for a designer to select the grip and appearance aesthetics that are appropriate for the tastes of the customer desiring the product development and design.

It is an object to provide a system and method for how the touch aesthetics, the grip aesthetics and the appearance aesthetics can be varied over a wide range to give improved products.

### SUMMARY OF THE INVENTION

The objects above are achieved by providing a method for providing a microstructured surface comprising the steps of selecting a material having a desired hardness for a given application; selecting a microstructure pattern having an arrangement of microfeatures to provide at least one desired touch aesthetic to be applied to said material, wherein the width and aspect ratio of the microstructures are configured to provide said desired touch aesthetic for the hardness of the material selected; selecting said microstructure pattern to further include at least one desired physical property independent of said touch aesthetic to be applied to said material, wherein at least one of a pitch and spacing of said microfeatures is configures to provide said desired physical property selected from the group consisting of friction coefficient and grip force; determining the dimensions of said microstructure pattern to be applied to the surface of said material according to said desired physical properties, desired touch aesthetics and material hardness; and, engineering the material with said microstructure pattern by forming a negative of the microstructure pattern and providing an end product in the selected material from the negative having the microstructure patterned with the desired physical and aesthetic properties.

In a further advantageous embodiment, said material has between about 30 Shore A to 95 Shore A hardness.

In a further advantageous embodiment, said microfeatures range from between about 10 μm to about 500 μm.

In a further advantageous embodiment, said aspect ratio is from about 0.1 to 5.0 as calculated by

$$\frac{Depth}{Width}$$

for a given microfeature.

In a further advantageous embodiment, said physical property of said microstructure pattern provides a grip force of at least about 35N to at least one of skin and fabric.

In a further advantageous embodiment, said touch aesthetic is selected from the group consisting of prickly, firm grip and comfortable, mink/cashmere, velvet, soft slick, firm rough painless, and soft rough, and combinations thereof.

In a further advantageous embodiment, said microstructure pattern having touch aesthetics of prickly or firm grip comfortable has microfeatures with a cross section width in the range of 20 μm to 200 μm, a spacing ratio calculated by

$$\frac{space}{width}$$

from 1.0 to 4.0, and an aspect ratio in the range of 1 to 5.

In a further advantageous embodiment, said microstructure pattern having touch aesthetics of prickly or firm grip comfortable has microfeatures with a sidewall draft angle from 0° to about 45°, corner radii in a range from 0% to about 50%.

In a further advantageous embodiment, a given microfeatures cross section has a shape selected from the group consisting of circle, rectangular, square, triangular, oval, polygonal, and line.

In a further advantageous embodiment, said microfeatures comprise at least one of recesses and pillars on the surface of said material.

In a further advantageous embodiment, said microfeatures comprise at least one of unstacked and stacked arrangements.

In a further advantageous embodiment, said microstructure pattern having touch aesthetics of mink/cashmere has microfeatures with a cross section diameter in the range of 20 μm to 100 μm, spacing ratio in the range of 0.7 to 4.0, and an aspect ratio in the range of 1.0 to 5.0.

In a further advantageous embodiment, said microstructure pattern having touch aesthetics of mink/cashmere has microfeatures with a sidewall draft from 0° to 10°, corner radii in the range of 0% to 50%.

In a further advantageous embodiment, said microstructure pattern having a touch aesthetic of Velvet has microfeatures with a cross section diameter in the range of 70 μm and 300 μm, spacing ration in the range of 1.0 to 4.0, and an aspect ratio in the range of 1.0 to 5.0.

In a further advantageous embodiment, said microstructure pattern having a touch aesthetic of Velvet has microfeatures with a sidewall draft in the range of 0° to 10°.

In a further advantageous embodiment, said microstructure pattern having a touch aesthetic of soft slick has microfeatures with an aspect ratio in the range of 0.1 to 2.0, spacing ratio in the range of 0.29 to 3.0, and a cross section diameter in the range of 20 μm to 70 μm.

In a further advantageous embodiment, said microstructure pattern having a touch aesthetic of soft rough on a material having a 60 Shore A value or less includes microfeatures with an aspect ratio in the range of 0.1 to 2.0, spacing ratio in the range of 1.0 to 2.5, and a cross section diameter in the range of 80 μm to 400 μm.

In a further advantageous embodiment, said microstructure pattern having a touch aesthetic of firm rough on a material having a Shore A value greater than about 60 includes microfeatures with an aspect ratio in the range of 0.1 to 2.0, spacing ratio in the range of 1.0 to 2.5, and a cross section diameter in the range of 80 μm to 400 μm.

The objectives are further achieved by a method for providing a microstructured surface comprising the steps of providing a touch map having an arrangement of microstructure patterns located across the surface of said map that define zones with unique touch aesthetics, wherein each zone is correlated with specific width and aspect ratios of microfeatures and a specific material hardness that combine to provide a given said touch aesthetic to each of said zones; selecting at least one desired touch aesthetic from said zones on said touch map; selecting a material having a hardness correlated with at least one of the selected said zones of said touch map for providing a selected said touch aesthetic to said material; selecting a microstructure pattern having an arrangement of microfeatures corresponding to the specific width and aspect ratios of microfeatures providing the touch aesthetic of the selected said zone for applying to said material; applying the dimensions of said microstructure pattern to a surface of said material to provide said material with said at least one touch aesthetic selected from said zones on said touch map.

In a further advantageous embodiment, a transition zone is included of about 20 μm or less to provide differing touch aesthetics between zones of said touch map.

### BRIEF DESCRIPTION OF THE DRAWINGS

The description of the invention will be explained with reference to the following figures:

FIG. 1 is a schematic of aspects of the present invention;

FIG. 2 is a schematic of aspects of the present invention;

FIG. 3 is various views of aspects of the present invention;

FIGS. 4A through 4B are various views of aspects of the invention;

FIG. 4C is a top down view of aspects of the invention;

FIG. 5A is various view of aspects of the invention;

FIGS. 5B through 5D are various top down views of aspects of the invention;

FIG. 6A is various view of aspects of the invention;

FIG. 6B is a top down view of aspects of the invention; through 6C are various views of aspects of the invention;

FIGS. 7A through 7F are top down view of aspects of the invention;

FIGS. 7G and 7H are perspective views of aspects of the invention;

FIG. 7I is a top down view of aspects of the invention; and,

FIG. 7J is a perspective views of aspects of the invention.

It will be understood by those skilled in the art that one or more aspects of this invention can meet certain objectives, while one or more other aspects can meet certain other objectives. Each objective may not apply equally, in all its respects, to every aspect of this invention. As such, the preceding objects can be viewed in the alternative with respect to any one aspect of this invention. These and other objects and features of the invention will become more fully apparent when the following detailed description is read in conjunction with the accompanying figures and examples. However, it is to be understood that both the foregoing summary of the invention and the following detailed description are of a preferred embodiment and not restrictive of the invention or other alternate embodiments of the invention. In particular, while the invention is described herein with reference to a number of specific embodiments, it will be appreciated that the description is illustrative of the invention and is not constructed as limiting of the invention. Various modifications and applications may occur to those who are skilled in the art, without departing from the spirit and the scope of the invention, as described by the appended claims. Likewise, other objects, features, benefits and advantages of the present invention will be apparent from this summary and certain embodiments described below, and will be readily apparent to those skilled in the art. Such objects, features, benefits and advantages will be apparent from the above in conjunction with the accompanying examples, data, figures and all reasonable inferences to be drawn therefrom, alone or with consideration of the references incorporated herein.

### DETAILED DESCRIPTION OF THE INVENTION

In general, the terms and phrases used herein have their art-recognized meaning, which can be found by reference to standard texts, journal references and contexts known to those skilled in the art.

Unless specifically stated, terms and phrases used in this document, and variations thereof, unless otherwise expressly stated, should be construed as open ended as opposed to limiting. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise.

Furthermore, although items, elements or components of the disclosure may be described or claimed in the singular, the plural is contemplated to be within the scope thereof unless limitation to the singular is explicitly stated. The presence of broadening words and phrases such as “one or more,” “at least,” “but not limited to” or other like phrases in some instances shall not be read to mean that the narrower case is intended or required in instances where such broadening phrases may be absent.

This invention provides a microstructured surface and method of manufacturing such surfaces to provide predictable and consistent touch aesthetics, especially with features in the 20 μm to 300 μm range. The touch aesthetics can be engineered and controlled using manufacturing processes such as those found in U.S. Pat. No. 8,720,047, incorporated by reference in its entirety. Referring to the following Table 1, physical properties for manmade materials having microstructures with microstructured patterns have corresponding physical properties and aspect ratios from 0.1 to 5.0:

TABLE 1

| | | | Width | | Pitch | | Depth | | | | |
|---|---|---|---|---|---|---|---|---|---|---|---|
| | | Pattern | (μm) | | (μm) | | (μm) | | Aspect | Spacing | |
| No. | Material | ID | L1 + L2 | Shape | L1 + L2 | Lattice | L1 + L2 | Spacing | Ratio | Ratio | Touch Aesthetic |
| 1 | Polypropylene | H021AP | 100.00 | square | 350.00 | triangular | 400.00 | 250.00 | 4.00 | 2.50 | Prickly, Firm Grip, |
| | | | | | | | | | | | Comfortable |
| 2 | Polypropylene | H021BP | 100.00 | square | 350.00 | triangular | 150.00 | 250.00 | 1.50 | 2.50 | Prickly, Firm Grip, |
| | | | | | | | | | | | Comfortable |
| 3 | Polypropylene | H171AP | 100.00 | circle | 400.00 | triangular | 100.00 | 300.00 | 1.00 | 3.00 | Prickly, Firm Grip, |
| | | | | | | | | | | | Comfortable |
| 4 | Polypropylene | H034AP | 30.00 | circle | 85.00 | rectangular | 40.00 | 55.00 | 1.33 | 1.83 | Prickly, Firm Grip, |
| | | | | | | | | | | | Comfortable |
| 5 | Polypropylene | H188AP | 150.00 | circle | 350.00 | rectangular | 200.00 | 200.00 | 1.33 | 1.33 | Prickly, Firm Grip, |
| | | | | | | | | | | | Comfortable |
| 6 | Polypropylene | H189AP | 250.00 | circle | 850.00 | rectangular | 500.00 | 600.00 | 2.00 | 2.40 | Prickly, Firm Grip, |
| | | | | | | | | | | | Comfortable |
| 7 | Polypropylene | H210AP | 200.00 | circle | 400.00 | rectangular | 200.00 | 200.00 | 1.00 | 1.00 | Prickly, Firm Grip, |
| | | | | | | | | | | | Comfortable |
| 8 | Polypropylene | H195AP | 100.00 | circle | 1000.00 | triangular | 150.00 | 900.00 | 1.50 | 9.00 | Prickly, Firm Grip, |
| | | | | | | | | | | | Comfortable |
| 9 | Polypropylene | H156AP | 50.00 | circle | 200.00 | triangular | 200.00 | 150.00 | 4.00 | 3.00 | Prickly, Firm Grip, |
| | | | | | | | | | | | Comfortable |
| 10 | 55A Silicone | H001AP | 50.00 | square | 100.00 | rectangular | 70.00 | 50.00 | 1.40 | 1.00 | Mink/Cashmere |
| 11 | 55A Silicone | H001BP | 50.00 | square | 100.00 | rectangular | 200.00 | 50.00 | 4.00 | 1.00 | Mink/Cashmere |
| 12 | 55A Silicone | H023AP | 50.00 | square | 85.00 | triangular | 100.00 | 35.00 | 2.00 | 0.70 | Mink/Cashmere |
| 13 | 55A Silicone | H012AP | 25.00 | square | 50.00 | triangular | 115.00 | 25.00 | 4.60 | 1.00 | Mink/Cashmere |
| 14 | 55A Silicone | H021AP | 100.00 | square | 350.00 | triangular | 400.00 | 250.00 | 4.00 | 2.50 | Velvet |
| 15 | 55A Silicone | H021BP | 100 | square | 350 | triangular | 150 | 250.00 | 1.50 | 2.50 | Velvet |
| 16 | 55A Silicone | H190AP | 200 | circle | 500 | rectangular | 600 | 300.00 | 3.00 | 1.50 | Velvet |
| 17 | 55A Silicone | H191AP | 150 | circle | 450 | rectangular | 450 | 300.00 | 3.00 | 2.00 | Velvet |

The aspect ratio can be calculated by

$$\frac{Depth}{Width} .$$

By engineering and manufacturing the microstructured patterns with the various surfaces and physical properties, the surfaces created can include touch aesthetics taken from the group consisting of Prickly (prickle), Firm Grip and Comfortable; Mink/Cashmere, and Velvet. Touch aesthetics can be engineered by a combination of certain materials with specific hardness physical properties, microstructured patterns, and cross section widths for the microfeatures of the microstructure. The touch aesthetics, based upon engineering variation in these physical properties can transition from one touch aesthetics to another. Commonly these products are made by molding rubber or plastics. The invention also applies to other manufacturing methods including roll-to-toll processing, laser engraving, stamping, machining, or casting; and can be extended to other materials including metals and ceramics.

The sensation of touch occurs in the micron size range from about 10 microns to about 500 microns. Below this size range, surfaces feel uniformly smooth and may be slick, sticky, or have stick slip behavior depending on the material. Above this range, our skin and fingers perceive individual features and the surfaces on those features rather than the surfaces themselves. Parameters included in this invention are material hardness, microfeature width, and microfeature aspect ratio (height relative to width). An additional parameter, feature pitch (center to center distance) or spacing (pitch minus width) can be used to adjust friction coefficient and grip. The microfeatures that deliver touch and grip aesthetics, can conformally cover larger appearance features. The microfeatures can be visible to the naked eye or invisible.

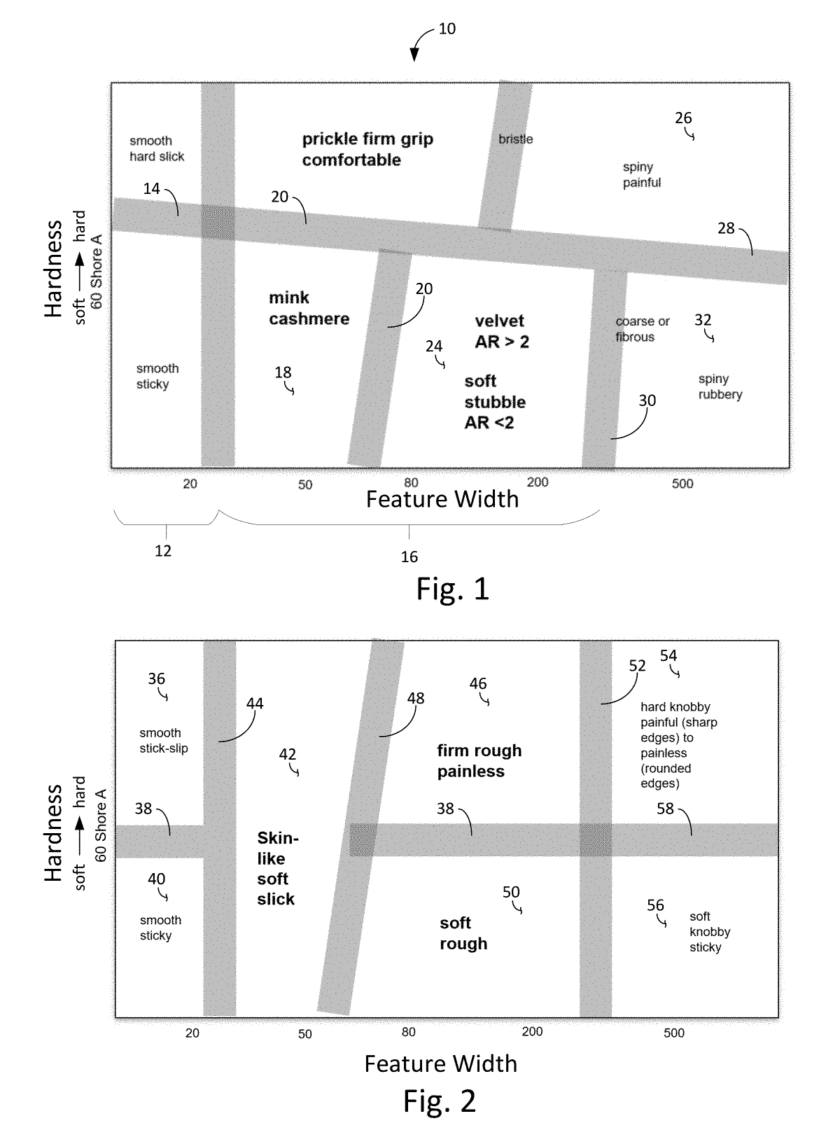

Referring to FIG. 1, the touch aesthetics map 10 is shown that can be provided with engineered surfaces of the present invention. There is a section of touch aesthetics that can be produced with polishing or with smooth finishes on harder materials such as those with Shore A values of 90 or higher. With these materials, including those in Table 1, when the surface is polished or fairly flat, with microfeatures having less than about 20 μm cross section diameters, the touch aesthetics are smooth sticky to smoother hard slick to the touch, according to the hardness of the material. These touch aesthetics in zone 12 have a transition area 14 between sticky to hard slick as the material hardness is varied. When the cross section diameter is engineered in the range of about 20 μm to about 300 μm, as shown in zone 16, there are several touch aesthetics provided. The mink cashmere zone 18 is in the range of about 20 μm to 70 μm and disposed on a generally soft material. There is a transition zone 20 between zone 18 and that of zone 22, prickle, firm grip, comfortable. There is also a transition zone 20 between zone 18 and zone 24, velvet (when the aspect ratio is about 2 or greater) and soft stubble (when the aspect ratio is about 2 or less). As the hardness of the material increases and the microfeature cross section diameter increases, the touch aesthetics become spiny painful in zone 26. As the material hardness drops with microfeature cross section widths in excess of about 250 μm, the touch aesthetics transition through transition zones 28 and/or 30 to a spiny rubbery in zone 32.

Referring to the following Table 2, physical properties for manmade materials having microfeatures with microstructured patterns have corresponding physical properties and aspect ratios from 0.1 to 2.0:

TABLE 2

| | | Width | | Pitch | | Depth | | | | |
|---|---|---|---|---|---|---|---|---|---|---|
| | Pattern | (μm) | | (μm) | | (μm) | | Aspect | Spacing | |
| Material | ID | L1 + L2 | Shape | L1 + L2 | Lattice | L1 + L2 | Spacing | Ratio | Ratio | Touch Aesthetics |
| TPU | H086BH | 3 + 35 | circular holes | 6 + 45 | triangular | 4 + 10 | 10.00 | 0.29 | 0.29 | soft slick |
| Steel | H401AP | 41.00 | square pillars | 82.00 | rectangular | 20.50 | 41.00 | 0.50 | 1.00 | soft slick |
| | only L2 | | | | | | | | | |
| TPU | H064AP | 3 + 35 | circles | 6 + 40 | triangular | 5 + 30 | 5.00 | 0.86 | 0.14 | soft slick |
| TPU | H025AP | 25.00 | circles | 60.00 | triangular | 25.00 | 35.00 | 1.00 | 1.40 | soft slick |
| TPU | H034AP | 30.00 | circles | 85.00 | rectangular | 40.00 | 55.00 | 1.33 | 1.83 | soft slick |
| Steel | H002AP | 41.00 | round pillars | 82.00 | rectangular | 57.40 | 41.00 | 1.40 | 1.00 | soft slick |
| TPU | H003DP | 25 × 50 | ovals | 100.00 | rectangular | 70.00 | 50.00 | 1.40 | 1.00 | soft slick |
| Steel | H379AP | 41 × 20.5 | oval pillars | 82.00 | rectangular | 57.40 | 41.00 | 1.40 | 1.00 | soft slick |
| Steel | H049AP | 41.00 | lines pillars | 164.00 | lines | 61.50 | 123.00 | 1.50 | 3.00 | soft slick |
| TPU | H012CP | 25.00 | squares | 50.00 | triangular | 50.00 | 25.00 | 2.00 | 1.00 | soft slick |
| Apple glass | N/A | N/A | N/A | N/A | N/A | N/A | N/A | N/A | N/A | soft slick |
| touchpad | | | | | | | | | | |
| TPU | H160CP | 10 + 100 | circles | 20 + 200 | triangular | 20 + 50 | 100.00 | 0.50 | 1.00 | soft rough/firm rough |
| TPU | H190AP | 200.00 | circles | 500.00 | rectangular | 200.00 | 300.00 | 1.00 | 1.50 | soft rough/firm rough |
| TPU | H021BP | 100.00 | squares | 350.00 | triangular | 150.00 | 250.00 | 1.50 | 2.50 | soft rough/firm rough |
| Rubber tire | N/A | N/A | N/A | N/A | N/A | N/A | N/A | N/A | N/A | soft knobby sticky |
| thread | | | | | | | | | | |
| Silicone | N/A | N/A | N/A | N/A | N/A | N/A | N/A | N/A | N/A | smooth sticky |
| Rubber | | | | | | | | | | |
| Polished | N/A | N/A | N/A | N/A | N/A | N/A | N/A | N/A | N/A | smooth stick-slip |
| surface | | | | | | | | | | |
| 40 grit | N/A | N/A | N/A | N/A | N/A | N/A | N/A | N/A | N/A | hard knobby painful |
| sand paper | | | | | | | | | | |
| Steel | H404AP | 82.00 | circular pillars | 164.00 | rectangular | 41.00 | 82.00 | 0.50 | 1.00 | firm rough |
| | only L2 | | | | | | | | | |
| Steel | H008AH | 164.00 | circular holes | 328.00 | triangular | 287.00 | 164.00 | 1.75 | 1.00 | firm rough |
| 600-300 grit | N/A | N/A | N/A | N/A | N/A | N/A | N/A | N/A | N/A | firm rough |
| sand paper | | | | | | | | | | |

Referring to FIG. 2, a further touch aesthetic map is shown. The aspect ratio is in the range of 0.1 to 1.0 and shows touch aesthetics for materials with Shore A value of about 40 to about 80 are shown. Zone 36 shows the engineered surface for material with the Shore A value in the 40 to 80 range and touch aesthetics of smooth stick-slip. As the material becomes softer, the touch aesthetics move through transition zone 38 into zone 40 smooth sticky. As the microfeature cross section diameter increases, and is cooperatively associated with the material and pattern, the touch aesthetics move to zone 42, soft slick through transition zone 44. With material that has Shore A values of 60 or greater, and microfeature cross sections with diameters of 50 μm or higher, the touch aesthetics zone of firm, rough, painless 46 is engineered and shows adjacent to transition zone 48. As the Shore A value is reduced, the touch aesthetics become soft rough in zone 50 through transition zone 52. Once the microfeatures cross section diameter increases through transition zone 52, the touch aesthetics become hard knobby painful in zone 54 or soft knobby sticky 56 depending upon the material hardness Shore A value. Zones 54 and 56 can be separated by transition zone 58.

In one embodiment, the material is made with various hard and soft materials, including polypropylene (60 shore D), 17-4PH stainless steel, 1010 carbon steel, 50 shore A silicone, 40 shore A silicone, 60 shore A TPU (thermoplastic polyurethane), 80 shore A TPU, 93 shore A TPU and 60 shore D TPU.

The touch aesthetics resulting from the engineered microstructured surfaces can be prickly and can be characterized as having individual microfeatures that have sufficient space between these features so that they can be resolved by rubbing against skin or scratching with fingernail. These microfeatures will not buckle when pressure is applied that is in excess of the pressure exerted on a surface by the average human hand. The microfeatures do not have a sufficient size to feel painful to the human when touched. A firm grip can be characterized by the increase in lateral sliding force relative to a non-micro structured surface. Comfortable can be characterized as not causing pain when touched or gripped, even when high force or high grip force is applied by a human hand.

To accomplish a touch aesthetic of Prickly, Firm Grip, Comfortable, one embodiment includes microstructures that have a microfeature cross section width in the range of 20 μm to 200 μm, a spacing ration calculated by

$$\frac{space}{width}$$

from 1.0 to 4.0. In one embodiment, the spacing ratio can be about 10 for certain materials that can include steel and brass. The aspect ratio can be in the range of 1 (having a width of 200 μm or less) and 5 (having a width of 50 μm or less). The microfeature can include a sidewall draft angle from 0° to about 45°.

For dry surfaces for each of the touch zones on FIGS. 1 and 2, at room temperature, that do not have an electrical charged, the following touch sensations can include the associated characteristics. The touch zones can transition from one to another. The transitions can be quite sharp occurring within a span of less than 20 microns.

TABLE 3

| | Material | Microfeature or | |
|---|---|---|---|
| Touch Zone | Hardness | Pillar Width | Aspect Ratio |
| Smooth Hard Slick | >75 Shore A | <30 micron | 1 to 5 |
| Smooth Sticky | <75 Shore A | <30 micron | 0.1 to 5 |
| Smooth Stick Slip | >75 Shore A | <30 micron | 0.01 to 1 |
| Prickle Firm Grip | >75 Shore A | >30 micron to | 1 to 5 |
| Comfortable | | <100 microns | |
| Spiny Painful | >75 Shore A | >100 microns | 1 to 5 |
| Spiny Rubbery | <75 Shore A | >100 microns | 1 to 5 |
| Velvet: | <75 Shore A | >70 micron to | 2 to 5 |
| | | <300 microns | |
| Soft Stubble | 30 Shore A to | >70 micron to | 1 to 2 |
| | hard metals, | <300 microns | |
| | ceramics or | | |
| | glass | | |
| Mink Cashmere | <75 Shore A | >20 micron to | 1 to 5 |
| | | <70 microns | |
| Skin-like Soft Slick | <75 Shore A | >20 micron to | 0.1 to 1 |
| | | <70 microns | |
| Soft Rough | <60 Shore A | >70 micron to | 0.1 to 1 |
| | | <300 microns | |
| Firm Rough Painless | >60 Shore A | >70 micron to | 0.1 to 1 |
| | | <300 microns | |
| Hard knobby painful | >60 Shore A | >100 microns | 0.1 to 1 |
| (pointed ends) | | | |
| Hard knobby painless | >60 Shore A | >100 microns | 0.1 to 1 |
| (rounded ends) | | | |
| Soft knobby sticky | <60 Shore A | >100 microns | 0.1 to 1 |

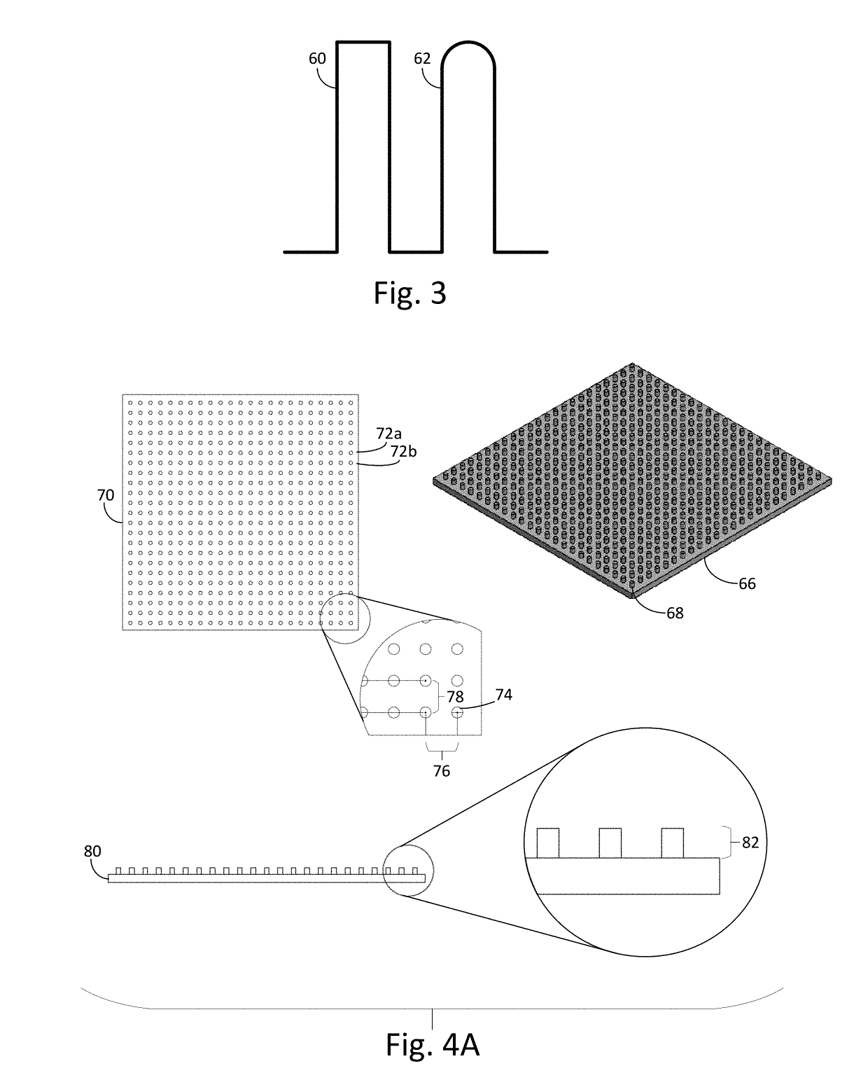

Referring to FIG. 3, the corner radii can have a range from 0% as shown by microfeature 60 to about 50% as shown by microfeature 62. The cross section itself can be round, oval, square, rectangular, or other geometric shape, symmetrical or asymmetrical. The microfeature can have one layer of structure or comprise of two or more layers of structures. When more than one structure is used, the layered structure can be used to reduce contract percentages further providing an engineered touch aesthetic from engineered microstructure patterned surface.

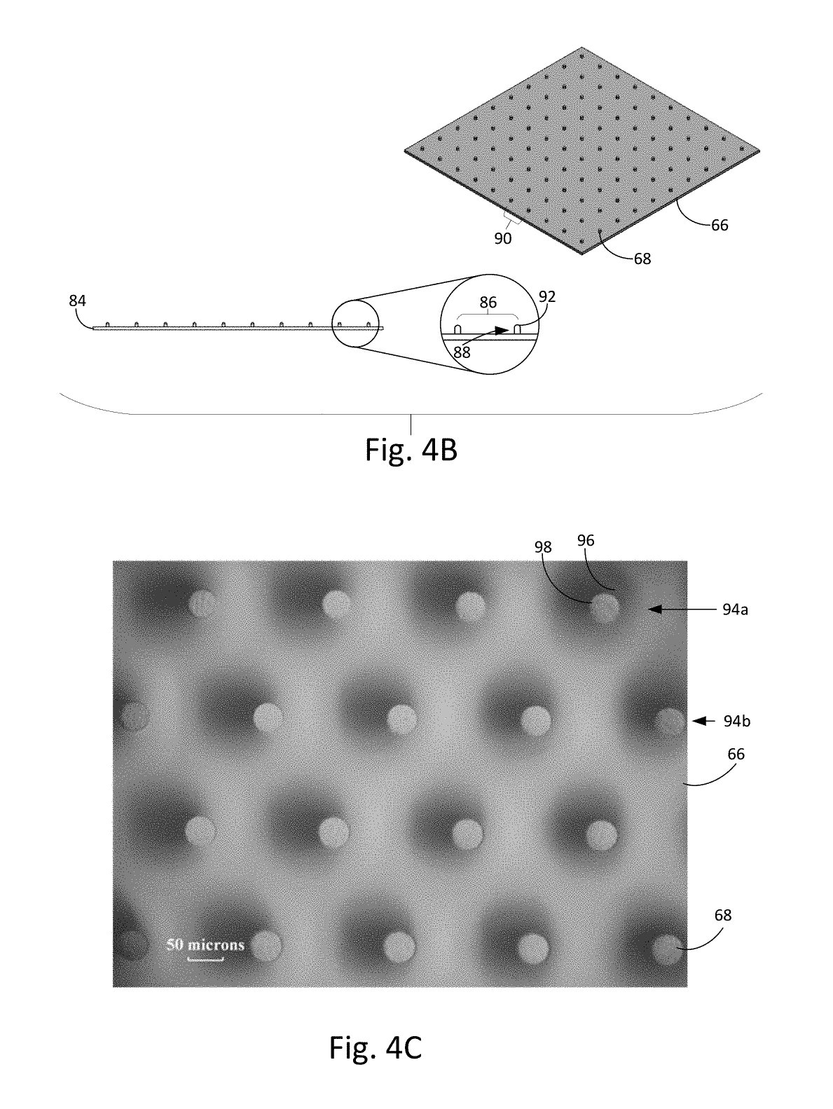

FIGS. 4A through 4C illustrate certain embodiments of patterns associated with the touch aesthetic Prickly, Firm Grip, Comfortable. Patterns can include H021AP, H021BP, H171AP, H034AP, 188AP, 189AP, H210AP, H195AP, and H156AP. FIG. 4A shows a microstructure pattern having a substrate 66 with pillars 68. The top view 70 shows the configuration where the pillars are arranged in a liner fashion without an offset between the rows 72a and 72b. The diameter 74 of a pillar is about 30.0 μm with a horizontal pitch 76 of about 85.0 μm and a vertical pitch 78 is about 85.0 μm. The side view 80 shows that the pillar can be about 40.0 μm in height 82. FIG. 4B shows a microstructure pattern having a substrate 66 with pillars 68. The side view 84 shows that the horizontal pitch 86 is about 100 μm. The vertical pitch 90 can be about 1000 μm as well. The pillar height 88 can be about 100 μm. The top of the pillar 92 can have a radius of about 0.05 degrees. FIG. 4C shows a microstructure pattern magnified about 200 times with a substrate 66 and pillars 68. A row of pillars 94a can be in an offset arrangement relative to an adjacent row of pillars 94b. The pillars can include a ramp surface 96 between the substrate and the top of the pillar. The top of the pillars can be generally flat and can include rounded top edges 98.

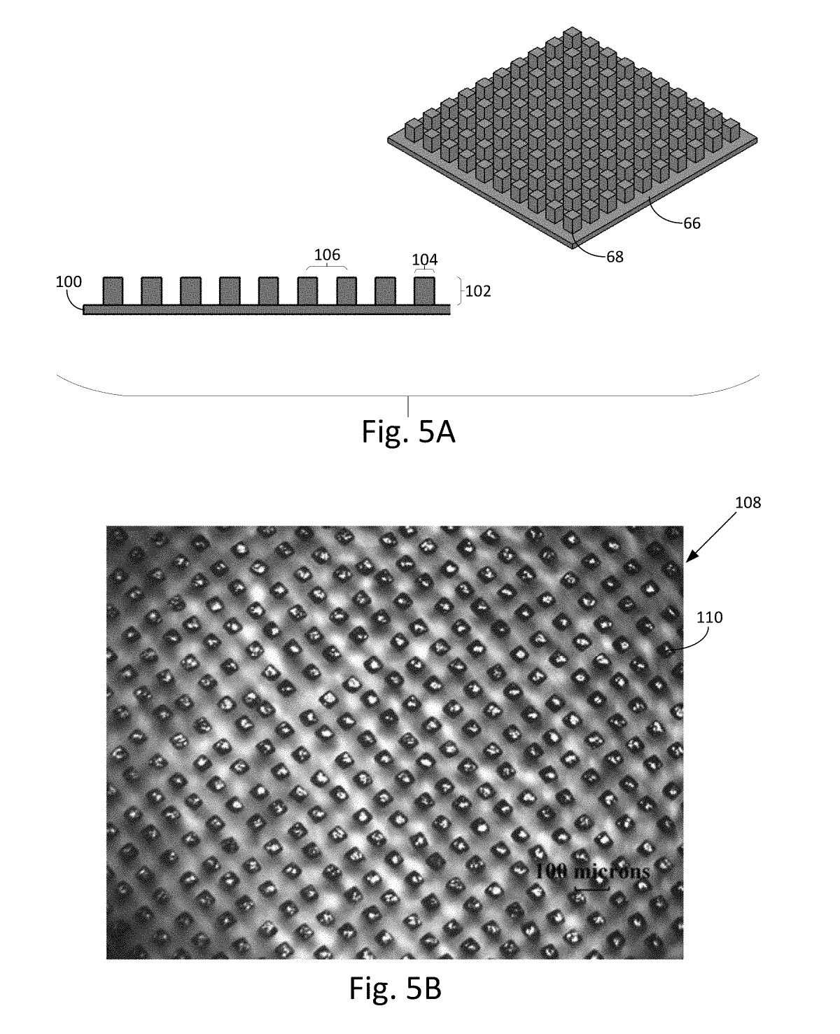

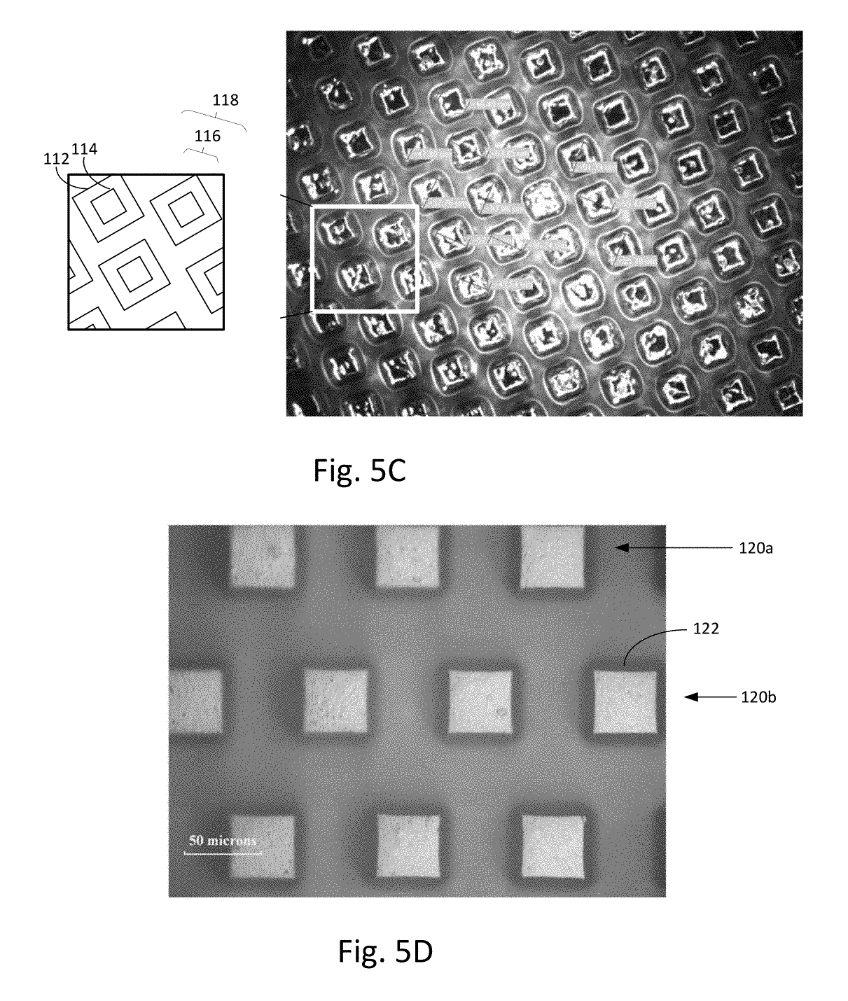

FIG. 5A shows a microstructure pattern having a substrate 66 with pillars 68. The pillars or microstructure features generally have a square cross section and are configured and arranged in a square or rectangular lattice geometry. In one embodiment, the pattern can include 100 pillars in an area of about 50 μm by 70 μm with about a 100 μm pitch. The side view 100 shows the pillars having about a 70.0 μm height 102, diameter 104 of about 50.0 μm and pitch 106 of about 100 μm. Referring to FIG. 5B, the rows of pillars 108 can be configured and arranged at about 45° relative to a substage edge. This figure is about a 200 times magnification. The pillars can include a rough top surface 110 and can include a second microfeature or pillars on the top surface. Referring to FIG. 5B, the pillars can be tapered from the base 112 to the top 114. The distance between a side wall edge to side wall edge of the pillar can be in the range of about 40.0 μm to 60.0 μm at the top 116 or the base 118. Referring to FIG. 5D, a pattern is shown magnified about 500 times showing pillars 68 with generally square cross sections. The pillars can be configured and arranged in an offset configuration where row 120a is offset from an adjacent row 120b. In one embodiment, the pullers can include a concave vertical side wall 122.

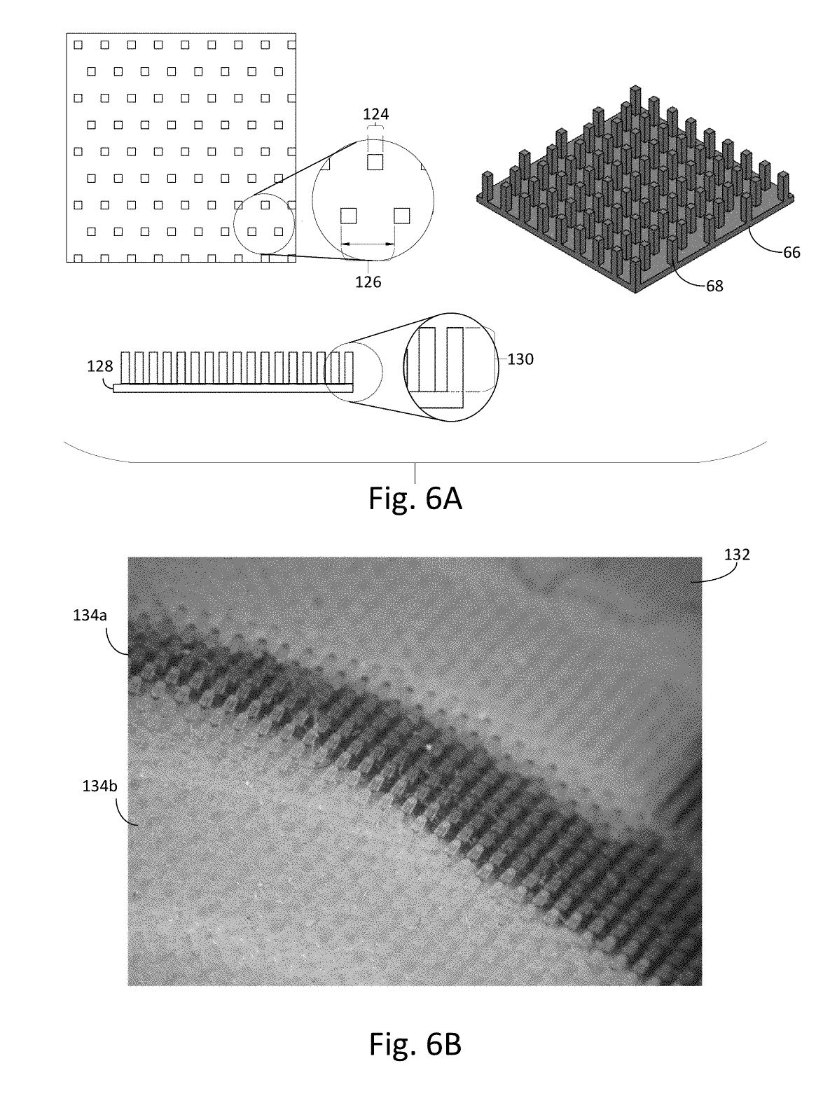

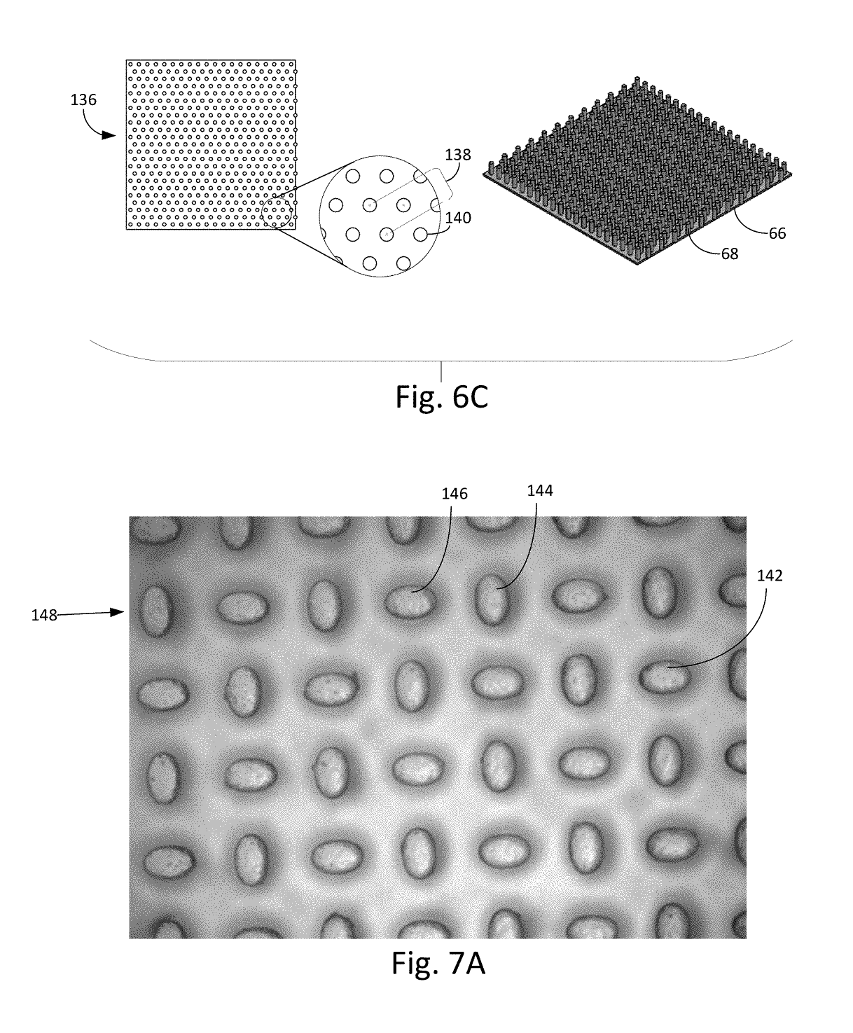

FIG. 6A shown shows a microstructure pattern having a substrate 66 with pillars 68. The pillars or microstructure features generally have a square cross section and are configured and arranged in a triangular lattice geometry. The pillars can include a width 124 of about 10 μm and a pitch 126 of about 35 μm. The side view 128 the pillars can have a height 130 of about 40.0 μm. Referring to FIG. 6N, the pattern can be molded over a fabric 132. The substrate and the pillars can be of a clear material allowing the colors, such as 134a and 134b, to be seem through the pattern. The substrate, microstructure features, patter or pillars can be made from a polymer, including a thermoplastic such as thermoplastic polyurethane. Referring to FIG. 6C, a microstructure pattern having a substrate 66 with pillars 68 is shown. The lattice equilateral configuration and arrangement 136. The pillars can include a pitch 138 of about 50 μm. The diameter 140 can be about 20 μm and a height of about 60 μm.

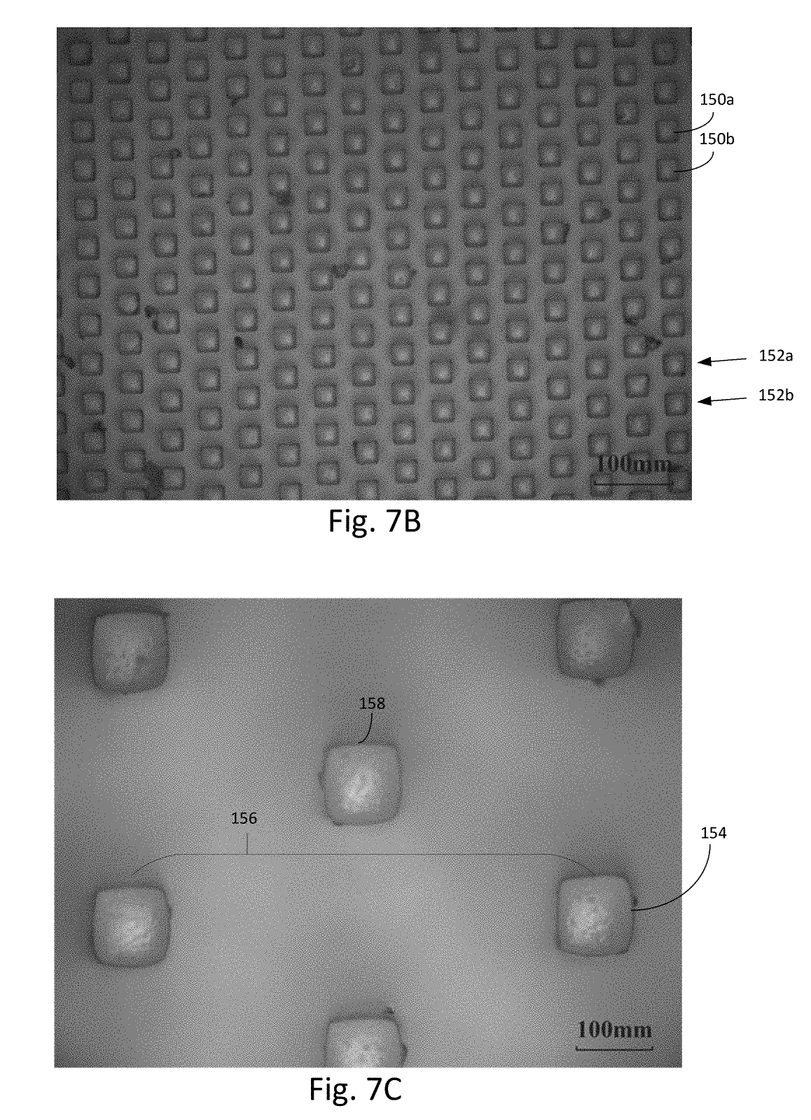

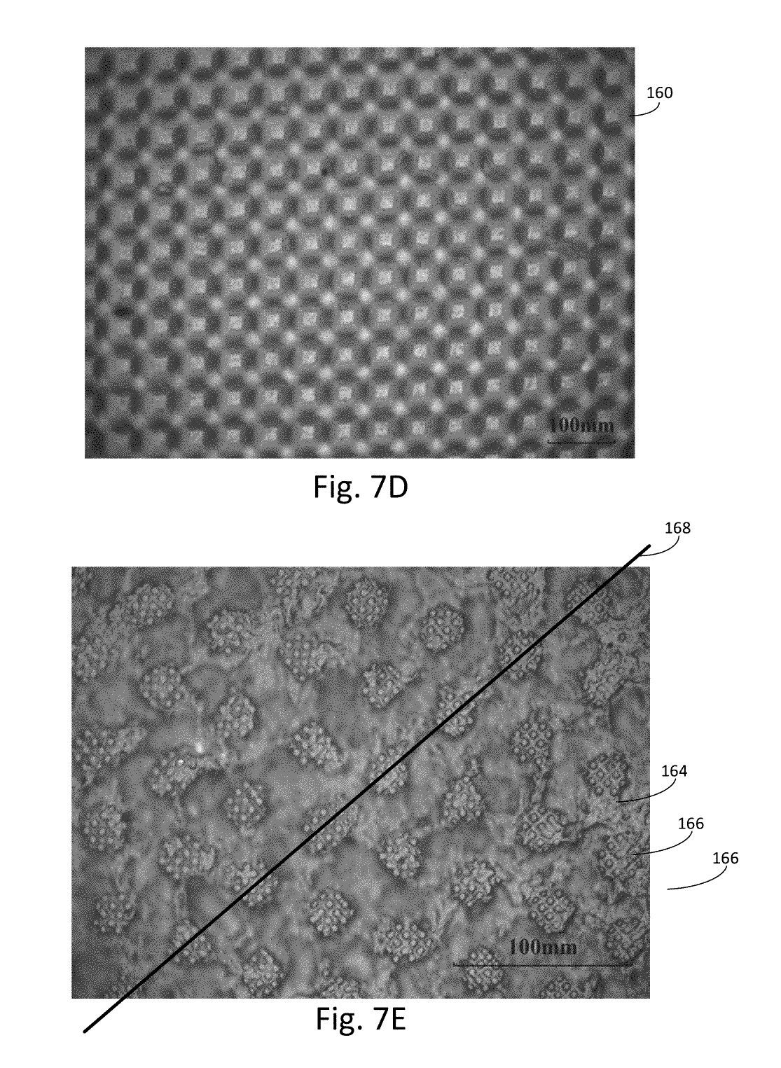

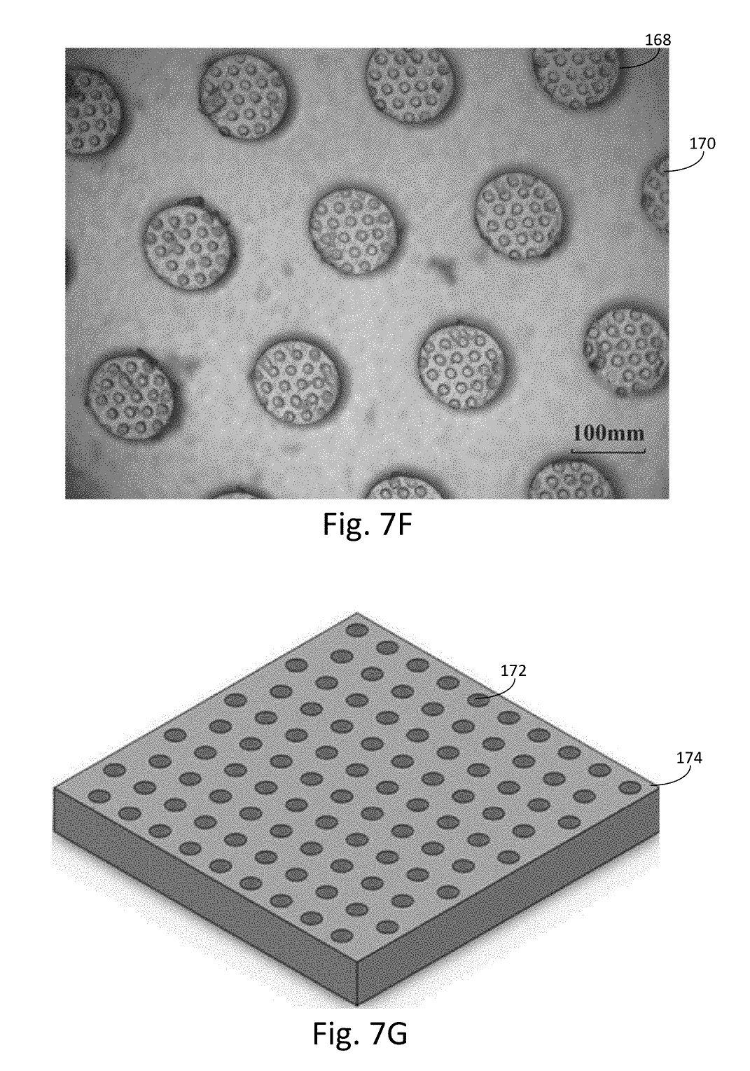

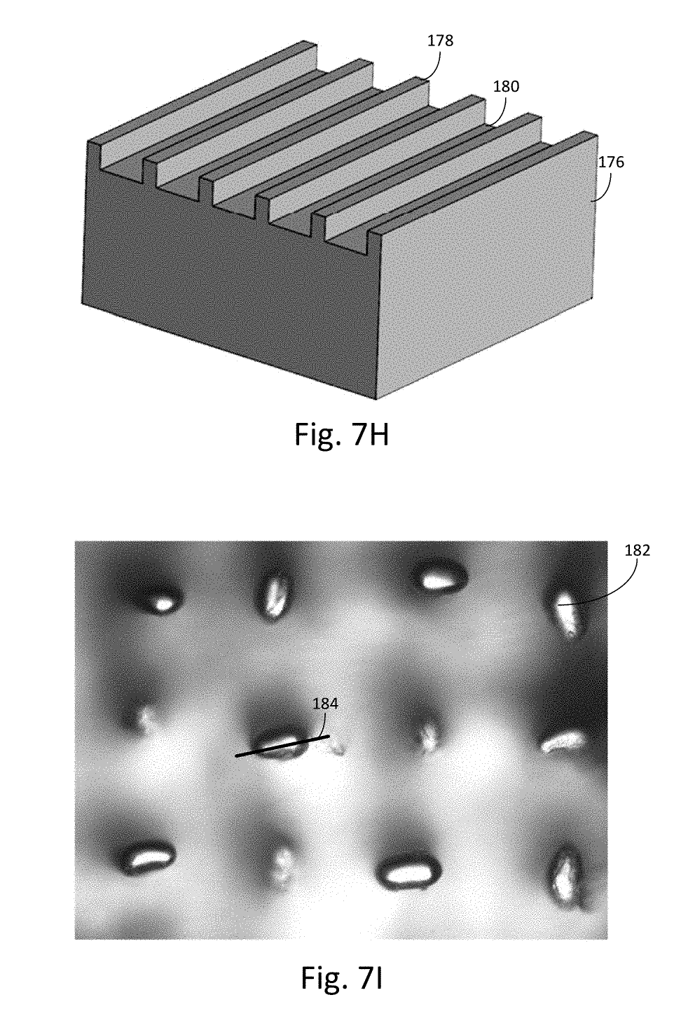

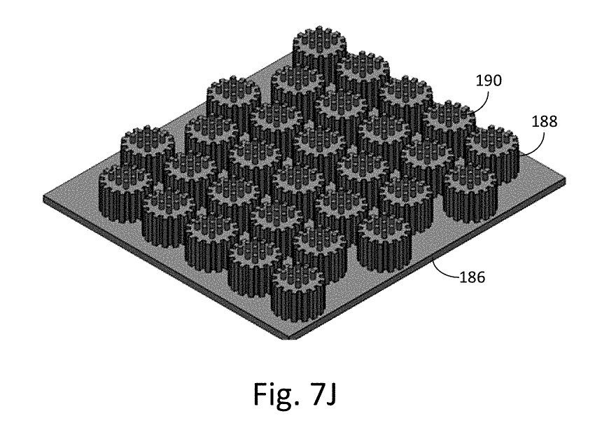

FIG. 7A shown a microstructure pattern having pillars that have a generally oval cross section 142. The pillars can have a vertical orientation 144 or a horizontal orientation 146. Along a row of pillars or features 148, the pillars can alternate between horizontal and vertical orientations symmetrically or asymmetrically. In an asymmetrically configuration or arrangement, adjacent pillar can be a first pillar that has a vertical orientation and a second pillar that has a horizontal orientation, two vertical orientations or two horizontal orientations. Referring to FIG. 7B, the Pillars can have generally a square cross section with the pitch between a first pillar 150a being about the same distance as the length of one side of the pillar. The pitch and length of one side can be about 50 μm. Row 152a can be offer set relative to adjacent row 152b. Referring to FIG. 7C, the pillar can include a convex side wall 154. The pitch 156 between pillars can be in the range of 5 to 10 times the length of a side wall 158 of the pillar. Referring to FIG. 7D, the pillars can be generally adjacent to each other at the side along the base 160. The pillar can include a flat top and be tapered from the base to the top. This configuration can define a eggshell configuration and arrangement of the pillars. Referring to FIG. 7E, the microstructures can include a roughed substrate surface 162. The roughed surface can be asymmetrically patterned. The substitute can include a raised layer 164 that can have pillars 166 disposed on the raised layer. The raised layer can be generally configured and arranged in rows so that an axis 168 an extend through the row. Referring to FIG. 7F, the pillars 170 can have a general oval cross section with pillars having smaller dimensions disposed on the top. Referring to FIG. 7G, the microfeatures need not be pillars, but can be voids 172 defined in the substrate 174. The voids can have an internal shape of a circle, oval, square, rectangle, polygon or asymmetrical shape. Referring to FIG. 7H, the microstructure can include a substrate 176 having ridges 178 defining slots 180. Referring to FIG. 7I, the pillars 182 can include an irregular oval cross section. A pillar axis 184 of a first pillar can be orientated 0 to 180 degrees relative to the pillar axis of the adjacent pillar. Referring to FIG. 7J, the substrate 186 can have disposed on it a first set of microfeatures or pillars 188. A second set of microfeatures 190 can be disposed on the top of the first set of microfeatures.

For the touch aesthetic Mink/Cashmere, the microfeatures are too small a diameter for humans to individually resolve the microfeatures by touching. Surfaces with this touch aesthetic tend to feel warm to the touch as a result of trapped insulating air between the microfeatures. The materials used to provide this touch aesthetic include those with Shore A hardness of 75 A or lower. The microfeature cross section diameter can be in the range of 20 μm to 100 μm. The spacing ratio can be in the range of 0.7 to 4.0. The aspect ratio can be in the range of 1.0 to 5.0. The sidewall draft can be from 0° to 10°. The corner radii can be in the range of 0% to 50%. Patterns than can be included in this touch aesthetic include H001AP, H001BP (with a 100 μm height), H023AP, H012AP with some shown in FIGS. 5A through 5D.

Touch aesthetic Velvet can be compared to the feeling of a tufted fabric. The microfeatures are large enough to individually resolve by human touching. The surface can feel warm as a result of trapped insulating air between the microfeatures. The materials used to provide this touch aesthetic include those with Shore A hardness of 75 A or lower. The microfeature cross section diameter can be in the range of 70 μm and 300 μm. The spacing ration can be in the range of 1.0 to 4.0. The aspect ratio can be in the range of 1.0 to 5.0. The sidewall draft can be in the range of 0° to 10°. Patterns that can be cooperative associated with this touch aesthetic include H021AP, H021BP, H190AP, H191AP including those shown in FIGS. 6A through 6C.

Touch aesthetic Soft Slick can be characterized by a feel with a reduced friction surface. The human cannot distinguish individual microfeatures. The surface feels continuous. Patterns that can be cooperative associated with this touch aesthetic include H086BH, H401AP (only L2), H064AP, H025AP, H034AP, H002AP, H003DP, H379AP, H049AP, H012CP. Touch aesthetic Firm Rough can be characterized where the human can begin to distinguish individual microfeatures. The surface is painless even with pressure and the surface provides for a firm grip when grip or touch force is applied. Patterns that can be cooperative associated with this touch aesthetic include H160CP, H190AP, H021BP, H404AP (only L2), H008AH. Touch aesthetic Soft Rough can be characterized as having a slight fuzzy to stubble feeling surface. This surface can feel soft but the human can begin to perceive texture on the surface. A surface can include one or more of the three touch aesthetics described above and can have the following physical properties.

The microstructure associated with the touch aesthetic soft slick surface on any material can have an aspect ratio in the range of 0.1 to 2.0, spacing ratio in the range of 0.29 to 3.0, and microstructure cross section diameter in the range of 20 μm to 70 μm.

The touch aesthetic achieved as soft rough surface on a soft material having a 60 Shore A value or less can have an aspect ratio in the range of 0.1 to 2.0, spacing ratio in the range of 1.0 to 2.5, and microfeature cross section diameter in the range of 80 μm to 400 μm.

The touch aesthetic achieved as firm rough surface on a hard material having a Shore A value greater than 60 can include an aspect ratio in the range of 0.1 to 2.0, spacing ratio in the range of 1.0 to 2.5, and microfeature cross section diameter in the range of 80 μm to 400 μm.

The microfeatures can include a cross-sectional shape that can be, but not limited to circle, rectangular, square, triangular, oval, polygonal, and line. The microfeatures can be holes (recesses) or pillars and unstacked or stacked on one another. FIGS. 7A through 7J illustrate patterns that can be cooperatively associated with these touch aesthetics.

In one embodiment, the engineered surface can be used for a trackpad (touch pads) that is commonly used for portable computers. Since the trackpad is from a manmade surface having touch aesthetics that are more than polished, smooth surfaces are desirable, especially when the surface should not be sticky. When manufactured, trackpads or touch pads are typically made from material with high Shore A values such as glass composites. Therefore, obtaining touch aesthetics that feel good, such as mink cashmere, velvet, soft rough and soft slick are difficult if not impossible to achieve. By using a microstructured surface of the present invention, these touch aesthetics can be imparted to the trackpads or touch pads without having to rely solely on material with high Shore A values.

In one embodiment, the engineered surface can be used for covers for electronic devices including phones and portable computers. Since electronic devices benefit from protective covers, it is beneficial to have such covers have sufficient soft material to adsorbe impact force while also having desirable touch aesthetics. Therefore, obtaining touch aesthetics that feel good, such as mink cashmere, velvet, soft rough and soft slick are desirable with material having mid to low Shore A values. By using a microstructured surface of the present invention, these touch aesthetics can be imparted to covers without reducing protective properties or feel.

Accordingly, those skilled in the art will recognize that the present invention can be applied to any number of materials used on a wide range of products, including but not limited to gripping surfaces on hand and power tools, sports equipment, medical devices, toys, and clothing, just to name a few.

While the present subject matter has been described in detail with respect to specific exemplary embodiments and methods thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art using the teachings disclosed herein.

What is claimed is:

1. A method for providing a microstructured surface comprising the steps of:
selecting a material having a desired hardness for a given application;
selecting a microstructure pattern having an arrangement of microfeatures to provide at least one desired touch aesthetic to be applied to said material, wherein the width and aspect ratio of the microstructures are configured to provide said desired touch aesthetic for the hardness of the material selected;
selecting said microstructure pattern to further include at least one desired physical property independent of said touch aesthetic to be applied to said material, wherein at least one of a pitch and spacing of said microfeatures is configures to provide said desired physical property selected from the group consisting of friction coefficient and grip force;
determining the dimensions of said microstructure pattern to be applied to the surface of said material according to said desired physical properties, desired touch aesthetics and material hardness; and,
engineering the material with said microstructure pattern by forming a negative of the microstructure pattern and providing an end product in the selected material from the negative having the microstructure patterned with the desired physical and aesthetic properties.

2. The method of claim 1 wherein said material has between about 30 Shore A to 95 Shore A hardness.

3. The method of claim 1 wherein said microfeatures range from between about 10 μm to about 500 μm

4. The method of claim 1 wherein said aspect ratio is from about 0.1 to 5.0 as calculated by
$$\frac{Depth}{Width}$$
for a given microfeature.

5. The method of claim 1 wherein said physical property of said microstructure pattern provides a grip force of at least about 35N to at least one of skin and fabric.

6. The method of claim 1 wherein said touch aesthetic is selected from the group consisting of prickly, firm grip and comfortable, mink/cashmere, velvet, soft slick, firm rough painless, and soft rough, and combinations thereof.

7. The method of claim 1 wherein said microstructure pattern having touch aesthetics of prickly or firm grip comfortable has microfeatures with a cross section width in the range of 20 μm to 200 μm, a spacing ratio calculated by
$$\frac{space}{width}$$
from 1.0 to 4.0, and an aspect ratio in the range of 1 to 5.

8. The method of claim 7 wherein said microstructure pattern having touch aesthetics of prickly or firm grip comfortable has microfeatures with a sidewall draft angle from 0° to about 45°, corner radii in a range from 0% to about 50%.

9. The method of claim 1 wherein a given microfeatures cross section has a shape selected from the group consisting of circle, rectangular, square, triangular, oval, polygonal, and line.

10. The method of claim 1 wherein said microfeatures comprise at least one of recesses and pillars on the surface of said material.

11. The method of claim 1 wherein said microfeatures comprise at least one of unstacked and stacked arrangements.

12. The method of claim 1 wherein said microstructure pattern having touch aesthetics of mink/cashmere has microfeatures with a cross section diameter in the range of 20 μm to 100 μm, spacing ratio in the range of 0.7 to 4.0, and an aspect ratio in the range of 1.0 to 5.0.

13. The method of claim 12 wherein said microstructure pattern having touch aesthetics of mink/cashmere has microfeatures with a sidewall draft from 0° to 10°, corner radii in the range of 0% to 50%.

14. The method of claim 1 wherein said microstructure pattern having a touch aesthetic of velvet has microfeatures with a cross section diameter in the range of 70 μm and 300 μm, spacing ration in the range of 1.0 to 4.0, and an aspect ratio in the range of 1.0 to 5.0.

15. The method of claim 14 wherein said microstructure pattern having a touch aesthetic of velvet has microfeatures with a sidewall draft in the range of 0° to 10°.

16. The method of claim 1 wherein said microstructure pattern having a touch aesthetic of soft slick has microfeatures with an aspect ratio in the range of 0.1 to 2.0, spacing ratio in the range of 0.29 to 3.0, and a cross section diameter in the range of 20 μm to 70 μm.

17. The method of claim 1 wherein said microstructure pattern having a touch aesthetic of soft rough on a material having a 60 Shore A value or less includes microfeatures with an aspect ratio in the range of 0.1 to 2.0, spacing ratio in the range of 1.0 to 2.5, and a cross section diameter in the range of 80 μm to 400 μm.

18. The method of claim 1 wherein said microstructure pattern having a touch aesthetic of firm rough on a material having a Shore A value greater than about 60 includes microfeatures with an aspect ratio in the range of 0.1 to 2.0, spacing ratio in the range of 1.0 to 2.5, and a cross section diameter in the range of 80 μm to 400 μm.

19. A method for providing a microstructured surface comprising the steps of:
providing a touch map having an arrangement of microstructure patterns located across the surface of said map that define zones with unique touch aesthetics, wherein each zone is correlated with specific width and aspect ratios of microfeatures and a specific material hardness that combine to provide a given said touch aesthetic to each of said zones;
selecting at least one desired touch aesthetic from said zones on said touch map;
selecting a material having a hardness correlated with at least one of the selected said zones of said touch map for providing a selected said touch aesthetic to said material;
selecting a microstructure pattern having an arrangement of microfeatures corresponding to the specific width and aspect ratios of microfeatures providing the touch aesthetic of the selected said zone for applying to said material;
applying the dimensions of said microstructure pattern to a surface of said material to provide said material with said at least one touch aesthetic selected from said zones on said touch map.

20. The method of claim 1 including a transition zone of about 20 μm or less to provide differing touch aesthetics between zones of said touch map.
